(19) United States
(12) Patent Application Publication
(10) Pub. No.: US 2024/0355365 A1
(43) Pub. Date: Oct. 24, 2024

(54) BOOST CAPACITOR SELECTIVELY AND CONCURRENTLY PROVIDING VOLTAGE BOOST TO MULTIPLE ASSIST CIRCUITS IN A MEMORY

(71) Applicant: International Business Machines Corporation, Armonk, NY (US)

(72) Inventors: Noam Jungmann, Holon (IL); Elazar Kachir, Tel Aviv (IL); Israel A. Wagner, Zichron Yaakov (IL); Bishan He, Poughkeepsie, NY (US); Rajiv Joshi, Yorktown Heights, NY (US)

(21) Appl. No.: 18/302,148

(22) Filed: Apr. 18, 2023

(51) Int. Cl. G11C 5/14

(52) U.S. Cl. CPC G11C 5/145

(57) ABSTRACT

An integrated circuit includes a semiconductor substrate and integrated circuitry on the semiconductor substrate. The integrated circuitry includes a static random access memory (SRAM) cell array and a first assist circuit and a differently configured second assist circuit. The first assist circuit is configured to apply a voltage boost to an access line utilized to access the SRAM cell array, and the second assist circuit is configured to apply a voltage boost to a voltage supply rail of the SRAM cell array. A common boost capacitor is coupled to selectively and concurrently provide a voltage boost to both the access line and the power rail via the first and second assist circuits, respectively.

### BACKGROUND OF THE INVENTION

This disclosure relates to memory and, in particular, to static random access memory (SRAM) employing a metal capacitor to assist read and/or write accesses to memory cells in the SRAM. Still more particularly, the present disclosure relates to a metal boost capacitor that may be utilized to selectively and concurrently provide a voltage boost to one or more different assist circuits to assist accesses to memory cells in the SRAM.

SRAM is often employed in embedded applications to provide high performance memory within an integrated circuit. For example, SRAM can be utilized to implement critical path storage, such as cache memory or an address translation structure, in a high performance processor. In such embedded applications, it is desirable to implement a relatively low upper supply voltage (V_{DD}) for the SRAM in order to reduce power dissipation and heat. However, to maintain high performance for read and write operations, it is also desirable to utilize various assist circuits to temporarily boost one or more line voltages above upper supply voltage V_{DD} or below a lower supply voltage V_{SS} (e.g., ground voltage).

In some prior art SRAMs, a boost capacitor is utilized within an assist circuit to boost a line voltage above upper supply voltage V_{DD} or below lower supply voltage V_{SS}. One known technique of implementing such a boost capacitor is by depositing a series of parallel metal lines over the SRAM cells. In such implementations, a first set of the metal lines (or “wires”) serve as a first “plate” of the capacitor, a disjoint second set of the metal lines serve as a second “plate” of the capacitor, and the desired capacitance is generated by the capacitive coupling between the first and second sets of metal lines. Although the use of a metal capacitor to provide read/write assist is convenient, decreasing minimum features sizes have reduced the chip area available for the metal lines forming a boost capacitor. Consequently, it has proved difficult to as a matter of floor planning to allocate adequate chip area for the respective boost capacitor of each of the various assist circuits of the SRAM.

### BRIEF SUMMARY

In view of the foregoing, the present application recognizes that it would be useful and desirable to provide a circuit and method that enable a common boost capacitor to be selectively and concurrently provide a voltage boost to one or multiple assist circuits in a SRAM.

In one or more embodiments, an integrated circuit includes a semiconductor substrate and integrated circuitry on the semiconductor substrate. The integrated circuitry includes a static random access memory (SRAM) cell array and a first assist circuit and a differently configured second assist circuit. The first assist circuit is configured to apply a voltage boost to an access line utilized to access the SRAM cell array, and the second assist circuit is configured to apply a voltage boost to a voltage supply rail of the SRAM cell array. A common boost capacitor is coupled to selectively and concurrently provide a voltage boost to both the access line and the power rail via the first and second assist circuits, respectively.

### BRIEF DESCRIPTION OF THE SEVERAL VIEWS OF THE DRAWINGS

FIG. 1 is a high-level block diagram of an exemplary integrated circuit in accordance with one embodiment;

FIG. 2 is a more detailed block diagram of an exemplary embodiment of a static random access memory (SRAM) macro in the integrated circuit of FIG. 1;

FIG. 3 illustrates a simplified view of a SRAM macro including a plurality of different assist circuits in accordance with one embodiment;

FIG. 4 is a more detailed block diagram of an exemplary boost circuit arrangement in accordance with one embodiment;

FIG. 5 is high-level logical flowchart of an exemplary method of selectively boosting the voltage of one or more assist circuits utilizing a common boost capacitor in accordance with one embodiment;

FIG. 6 is a timing diagram of the application of positive voltage boosts to a wordline and an upper cell supply voltage rail in accordance with one embodiment;

FIG. 7 is a block diagram of a negative boost circuit arrangement in accordance with one embodiment;

FIG. 8 is a timing diagram of the application of a negative voltage boost to a bitline of a SRAM cell array in accordance with one embodiment; and

FIG. 9 is a data flow diagram illustrating a design process.

### DETAILED DESCRIPTION

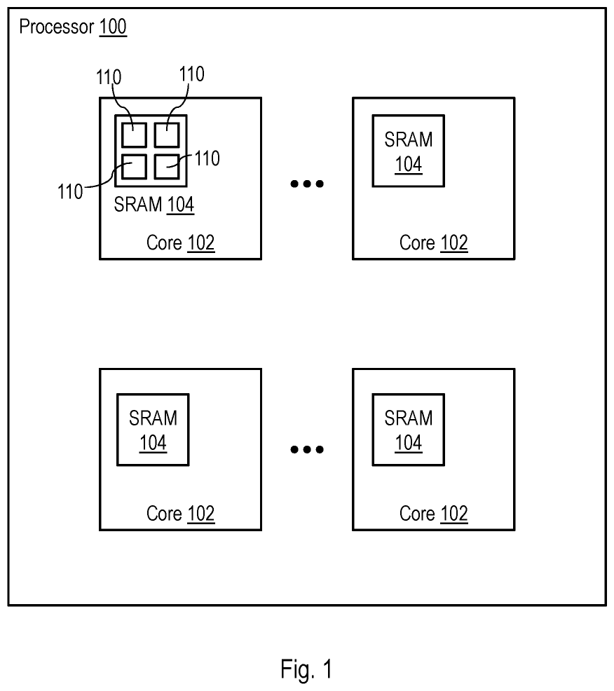

With reference to the figures and with particular reference to FIG. 1, there is illustrated a high-level block diagram of an exemplary integrated circuit in accordance with one embodiment. In this example, the integrated circuit is a processor 100, including a semiconductor substrate on which integrated circuit is fabricated in a manner known in the art. Processor 100 includes a plurality of cores 102 (e.g., 4, 8, 12, 16, 20, 32, etc.) for processing data and instructions in accordance with a selected instruction set architecture (e.g., x86, POWER, RISC5, ARM, Apple silicon, etc.). Although not required, in this example, each core 102 includes an embedded static random access memory (SRAM) 104 providing high performance (i.e., low access latency) storage for data and/or instructions processed by that core 102.

In the depicted embodiment, each SRAM 104 includes a plurality of independently controllable SRAM macros 110. In some implementations, processor 100 is configured to initially place a first subset of the SRAM macros 110 into service and to reserve a second subset of SRAM macros 110 as spare(s) that can be substituted for a failing or failed SRAM macro 110. Those skilled in the art will appreciate that in some embodiments, one or more of SRAMs 104 and/or SRAM macros 110 may be implemented within processor 100, but not within one of cores 102. Further, in some embodiments, one or more SRAM macros 110 may form a shared spare pool from which processor 100 can automatically allocate storage to any one of multiple cores 102, for example, in place of a failing or failed SRAM macro 110.

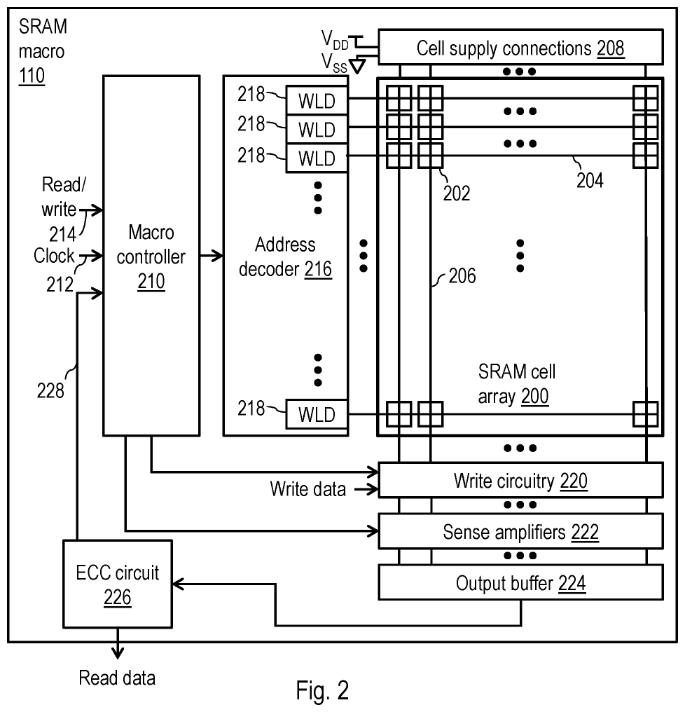

With reference now to FIG. 2, there is illustrated a more detailed block diagram of an exemplary embodiment of a static random access memory (SRAM) macro 110 in the integrated circuit of FIG. 1. SRAM macro 110 includes a SRAM cell array 200 including multiplicity of individual memory cells 202. Memory cells 202 are physically arranged in a matrix including a plurality of rows (e.g., M rows), each accessed via a respective wordline 204, and a plurality of columns (e.g., N columns), each accessed via respective bitline(s) 206 (generally, a pair of bitlines, including a bitline true (BLT) and a bitline complement (BLC)). If implemented in a conventional manner (i.e., as a 6T cell), each memory cell 202 includes a pair of cross-coupled inventers and two NMOS pass transistors connecting the inventers to a bitline pair (BLT and BLC), where the NMOS pass transistors are controlled by the relevant wordline 204. Memory cells 202 within SRAM cell array 200 are powered via cell supply connections 208 to an upper cell supply voltage rail having a nominal upper supply voltage V_{DD} (e.g., 0.8 V) and a lower supply voltage rail having a nominal lower supply voltage V_{SS} (e.g., ground).

SRAM macro 110 includes a macro controller 210 having a first input that receives a reference clock signal 212 and a second input that that receives read/write access commands 214, each specifying a target address. In response to these inputs, macro controller 210 orchestrates read and write accesses to the relevant memory cells 202 within SRAM cell array 200. In some embodiments, these accesses include, in addition to reads and writes of a full row of memory cells 202, a partial write to only a subset of the memory cells 202 comprising a row of memory cells 202. Macro controller 210 is coupled to an address decoder 216, to which macro controller 210 forwards the target address of each read or write command. Address decoder 216, which includes a wordline driver (WLD) 218 for each wordline 204, decodes the target address to identify a corresponding wordline 204. The wordline driver 218 for the identified wordline 204 then asserts its corresponding wordline 204 to access memory cells 202 in the associated row of SRAM cell array 200. For a write command, macro controller 210 also controls write circuitry 220 to apply write data received in conjunction with the write command to the relevant bit lines 206, thus updating the accessed memory cells 202. For a read command, assertion of the selected wordline 204 causes the bits stored in the memory cells 202 coupled to that wordline 204 to be read out onto bitlines 206, detected by sense amplifiers 222, and buffered in output buffer 224. The output data are passed to an error correcting code (ECC) circuit 226, which detects, and if possible, corrects, errors in the output data. The corrected output data are returned to a requestor as read data. ECC circuit 226 additionally reports, via signal line 228, any correctable errors (CEs) and uncorrectable errors (UEs) detected in the output data to macro controller 210. For CEs, ECC circuit 226 may optionally provide the corrected data to write circuitry 220 as write data in order to enable the corrected data to be written back into SRAM cell array 200.

In accordance with the disclosed inventions, SRAM macro 110 includes multiple assist circuits, where each such assist circuit is configured and coupled to selectively and temporarily boost a voltage of one or more conductive lines within SRAM cell array 200 either positively (a positive boost) or negatively (a negative boost) during a read or write access. As noted above, such assist circuits are conventionally employed with SRAMs to retain a desired level of performance while reducing baseline power dissipation and heat. For example, in some embodiments, SRAM macro 110 may employ such an assist circuit with wordline drivers 218 to enable wordline drivers 218 to boost a voltage pulse applied to wordlines 204 above upper supply voltage V_{DD} during read and/or write accesses to SRAM cell array 200. In some embodiments, SRAM macro 110 may alternatively or additionally include such an assist circuit within cell supply connections 208 in order to temporarily apply a positive boost to the voltage of the upper cell power supply rail of memory cells 202 and/or to temporarily apply a negative boost to the voltage on the lower cell power supply rail of memory cells 202. In some embodiments, SRAM macro 110 may alternatively or additionally include such assist circuits within write circuitry 220 to apply a boost (usually negative) to the precharge voltage applied to bitlines 206.

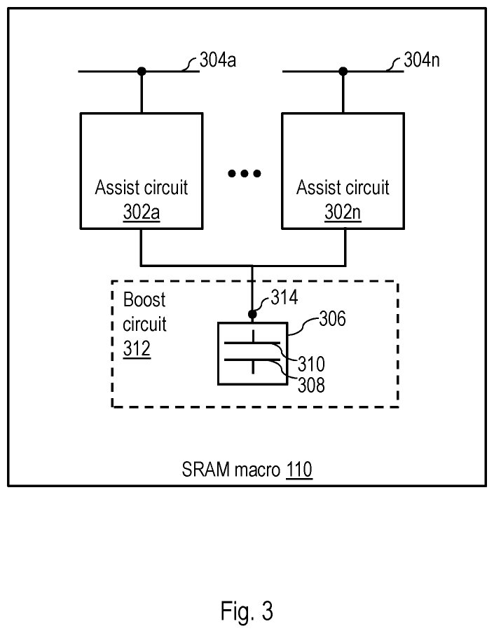

With reference now to FIG. 3, there is illustrated a simplified view of SRAM macro 110 of FIG. 2, which illustrates a plurality of different assist circuits in accordance with one embodiment. In this view, SRAM macro 110 includes a plurality of different assist circuits 302a, . . . , 302n as described above. Assist circuits 302 are of multiple different types and configurations and, in various implementations, can selectively apply either a positive boost or a negative boost present on a plate of boost capacitor 306 to the voltage on a respective conductive line 304a, . . . , 304n. In one example, assist circuit 302a may be a wordline assist circuit, and conductive line 304a may be a wordline 204 of SRAM cell array 200. Assist circuit 302n may be, for example, a cell voltage assist circuit, and conductive line 304n may be an upper power supply rail of memory cells 202. Yet another assist circuit 302 may be a bitline assist circuit coupled to selectively connect a voltage boost present on a plate of boost capacitor 306 to a bitline 206 of SRAM cell array 200.

In contrast to prior art circuits in which each assist circuit has its own respective boost capacitor, in the embodiment of FIG. 3, multiple different assist circuits 302a, . . . , 302n share a common boost capacitor 306 to which the multiple assist circuits 302a, . . . , 302n are coupled. In at least some embodiments, boost capacitor 306 is structured as is known in the art with parallel metal lines (or wires) deposited over SRAM macro 110, where the capacitance of the boost capacitor 306 is determined by the capacitive coupling between the first set of metal wires forming a first plate 308 and the second set of metal wires forming second plate 310. In the depicted embodiment, boost capacitor 306 is implemented as a component of a boost circuit 312 configured to control active first plate 308 to generate a boost voltage on second plate 310, which is coupled to assist circuits 302a, . . . , 302n at node 314. Although FIG. 3 illustrates boost capacitor 306 as a component of a boost circuit 312 that is distinct from assist circuits 302, those skilled in the art will appreciate that this illustration is for case of presentation and that in at least some embodiments boost capacitor 306 (and the circuitry utilized to develop the boost voltage on second plate 310) can be implemented as a component of one of assist circuits 302a, . . . , 302n. Although the specific details of assist circuits 302 and, if present, boost circuit 312, will vary based on application, in general, macro controller 210 controls boost circuit 312 to selectively and temporarily generate a boost voltage on node 314 coupled to second plate 310 of boost capacitor 306 and further controls one or more of assist circuits 302 to apply that boost voltage to one or more of conductive lines 304a, . . . , 304n.

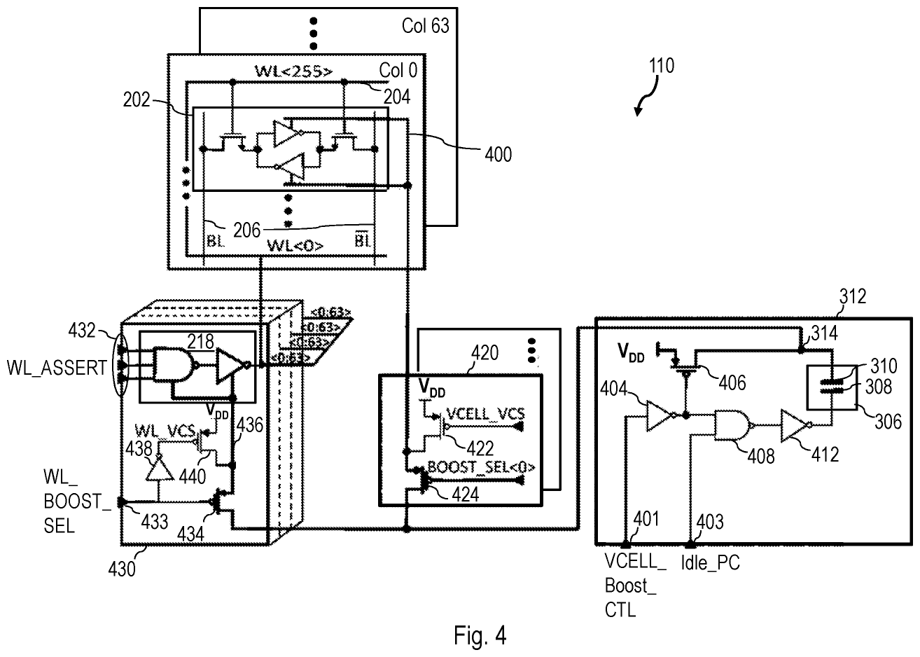

Referring now to FIG. 4, there is depicted a more detailed block diagram of a portion of SRAM macro 110 including a boost circuit arrangement in accordance with one embodiment. The example circuit of FIG. 4 is but one of many possible implementations of the high-level circuit arrangement illustrated in FIG. 3.

In the example of FIG. 4, memory cells 202 in SRAM cell array 200 are arranged in 256 rows, each accessed via a respective wordline 204, and 64 columns, each accessed via a respective bitline pair 206 (i.e., a bitline true (BL) and bitline complement (B̅L̅)). Memory cells 202 are each powered via an upper cell supply voltage rail 400. In this example, a common boost capacitor 306 can be employed to selectively provide a positive voltage boost to the voltage of either or both of a selected wordline 204 and an upper cell supply voltage rail 400.

In the embodiment of FIG. 4, the boost circuit arrangement of SRAM macro 110 includes a boost circuit 312, which can be implemented, for example, as part of cell supply connections 208 of FIG. 2. Boost circuit 312 has a first input 401 that receives a cell voltage boost control signal (VCELL_Boost_CTL) and a second input 403 that receives an idle precharge signal (Idle_PC). First input 401 is coupled to the input of an inverter 404 having an output coupled to the gate of a PMOS transistor 406 coupled between upper supply voltage V_{DD} and a node 314 connected to second plate 310 of boost capacitor 306. Boost circuit 402 additionally includes a two-input NAND gate 408 having a first input coupled to the output of inverter 404 and a second input coupled to receive a Idle_PC signal from second input 403. The output of NAND gate 408 is coupled through an inverter 412 to first plate 308 of boost capacitor 306, which is the active plate.

During an idle period between accesses to SRAM cell array 200, macro controller 210 sets the VCELL_Boost_CTL signal logic high (e.g., 0b1), causing PMOS transistor 406 to be turned on to charge node 314 connected to second plate 310 to upper supply voltage V_{DD}. In addition, macro controller 210 sets the Idle_PC signal logic high (e.g., 0b1), causing first plate 308 to be set to the opposite voltage state from second plate 310 (i.e., logic low). When a boost operation is active (e.g., during an access to SRAM cell array 200), macro controller 210 deasserts (e.g., switches to 0b0) the VCELL_Boost_CTL signal and continues to assert the Idle_PC signal. As a result, the output of NAND gate 408 changes from logic high to logic low, which switches the voltage on first plate 308 from the logic low state to the logic high state to provide a coupling action to second plate 310 and thus positively boost the voltage of second plate 310 and node 314. Deasserting the VCELL_Boost_CTL signal also disconnects second plate 310 from upper supply voltage V_{DD}, enabling the voltage of second plate 310 to float in order to allow the coupling effect of first plate 308 switching states to impact the voltage state of second plate 310.

The boost circuit arrangement of FIG. 4 additionally includes a respective column assist circuit 420 for each of the columns of SRAM cell array 200. Each column assist circuit 420 includes a first PMOS transistor 422 having a source coupled to upper supply voltage V_{DD}, a drain coupled to the upper voltage supply rails 400 of the memory cells 202 in a given column of SRAM cell array 200, and a gate coupled to receive an active-low column select signal (VCELL_VCS). Column assist circuit 420 additionally includes a second PMOS transistor 424 having a source coupled to the upper voltage supply rails 400 of the memory cells 202 in a given column of SRAM cell array 200, a drain coupled to node 314 of boost circuit 402, and a gate coupled to receive an active-low boost select signal (BOOST_SEL). In order to apply a positive boost present on node 314 to the voltage on the upper voltage supply rails 400 of memory cells 202 in a given column, macro controller 210 deasserts column select signal (VCELL_VCS) (i.e., VCELL_VCS=0b1) and asserts boost select signal (BOOST_SEL) (i.e., BOOST_SEL=0b0), causing the voltage of the voltage supply rails 400 of memory cells 202 to be boosted above nominal upper supply voltage V_{DD} by the boost voltage present at node 314.

The boost circuit arrangement of FIG. 4 additionally includes a plurality of wordline assist circuits 430, which can each be integrated with a respective one of wordline drivers 218. In this embodiment, each wordline assist circuit 430 includes a first input 432 that receives a wordline assert signal (WL_ASSERT) from address decoder 216. The wordline assert signal causes a wordline driver 218 to assert or to deassert a corresponding wordline 204 for each access to SRAM cell array 200. Wordline assist circuit 430 additionally has a second input 433 that receives from macro controller 210 an active-low wordline boost select signal (WL_BOOST_SEL) that is set to logic low (e.g., 0b0) to indicate that a voltage boost is to be applied to the wordline and is set to logic high (e.g., 0b1) otherwise. If the wordline boost select (WL_BOOST_SEL) signal is logic low, the wordline boost select (WL_BOOST_SEL) signal turns on PMOS transistor 434, applying the boost voltage present on node 314 to wordline driver 218 via line 436. Line 436 is also coupled via PMOS transistor 440, which has a gate coupled to an output of an inverter 438 that receives the wordline boost select (WL_BOOST_SEL) signal as an input. If wordline boost select (WL_BOOST_SEL) signal is logic low, PMOS transistor 440 is turned off. If, however, wordline boost select (WL_BOOST_SEL) signal is logic high, PMOS transistor 440 turns on and connects upper supply voltage V_{DD} to wordline driver 218 via line 436. Thus, if the wordline assert signal is asserted, wordline driver 218 drives the wordline voltage to a higher boosted voltage if the wordline boost select (WL_BOOST_SEL) signal is logic low and drives the wordline voltage to V_{DD} if the wordline boost select (WL_BOOST_SEL) signal is logic high.

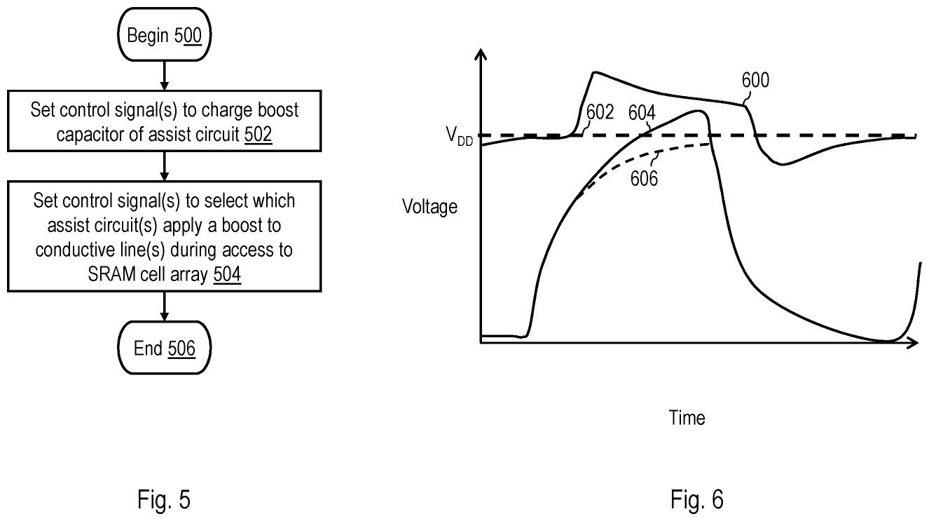

Referring now to FIG. 5, there is illustrated high-level logical flowchart of an exemplary method of selectively boosting the voltage of one or more assist circuits utilizing a common boost capacitor in accordance with one embodiment. To promote greater understanding, the method of FIG. 5 is described in conjunction with FIG. 4 and with FIG. 6, which is a timing diagram of the application of positive voltage boosts to a wordline and a cell supply voltage line in accordance with one embodiment.

The process of FIG. 5 begins at block 500 and then proceeds to block 502, which illustrates macro controller 210 setting appropriate values of control signals, such the VCELL_Boost_CTL and Idle_PC signals, to charge common boost capacitor 306 with a desired boost voltage in excess of a reference supply voltage. As described above, charging boost capacitor 306 in this manner may entail a number of substeps, including setting the first and second plates 308, 310 to opposite voltage states, floating the voltage of the second plate 310, and switching the voltage state of the active first plate 308. Next, at block 504, macro controller 210 sets one or more control signals to selectively apply the voltage present on common boost capacitor 306 to one or more conductive lines during an access to SRAM cell array 200. For example, if macro controller 210 asserts active-low BOOST_SEL signal of one or more column assist circuits 420, the voltage present on common boost capacitor 306 is applied to the upper cell supply voltage rails 400 of the relevant column(s), temporarily boosting the voltage of the upper cell supply voltage rails 400 of the memory cells 202 in the relevant column(s) to a voltage greater than nominal upper supply voltage V_{DD}, as shown at reference numeral 600 of FIG. 6. In the absence of application of a boost voltage, a column assist circuit 420 instead applies nominal upper supply voltage V_{DD} to the upper cell supply voltage rails 400 of the associated column of memory cells 202, as shown at reference numeral 602 of FIG. 6.

Similarly, if macro controller 210 asserts the active-low WL_BOOST_SEL signal for a given wordline 204, the associated wordline assist circuit 430 applies the voltage present on common boost capacitor 306 to the wordline 204, as shown at reference numeral 604 of FIG. 6. Absent assertion of the WL_BOOST_SEL signal for the accessed wordline 204, the wordline 204 has a lower peak voltage, as shown at reference numeral 606 of FIG. 6. Again, it should be noted that in the illustrated embodiment, common boost capacitor 306 can be utilized to boost the voltage on the upper cell supply voltage rails 400 of the accessed memory cells 202, on the accessed wordline 204, or on both the upper cell supply voltage rails 400 of the accessed memory cells 202 and the accessed wordline 204. It should also be noted that, in the depicted example, the boosted voltage level of the wordline 204 is greater than nominal upper supply voltage V_{DD}, but less than the boosted voltage level of upper cell supply voltage rail 400.

The implementation of a common boost capacitor for multiple assist circuits has several advantages. The use of a common boost capacitor increases writability by supplying a wordline boost during write operations and provides stability for read operations. In cases in which only a partial row of SRAM cells is written, application of a voltage boost to the wordline improves writability for the written memory cells and stability for the non-written memory cells. In addition, during read operations, performance (latency) is improved by application of a voltage boost to both the accessed wordline and upper cell supply voltage rails of the accessed memory cells. The use of a common boost capacitor for multiple different types of assist circuits provides better control over the boost levels and improved synchronization the timing of application of the boost voltages to the different conductive lines. Further, the use of a common boost capacitor for multiple different types of assist circuits reduces the wire resources and chip area required to implement a boost capacitor and improves integrated circuit yield by reducing the probability of a short circuit due to high metal density.

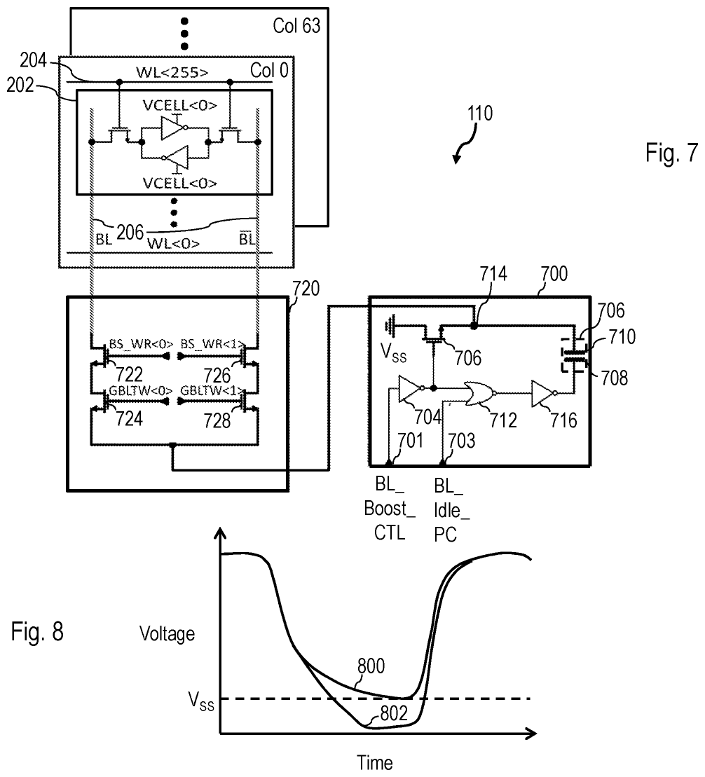

The present application additionally appreciates that writability of SRAM memory cells can also be improved by applying a negative boost voltage to bitlines of the SRAM cells to be written, where the negative boost can be selectively applied either alone or in combination with a positive wordline boost as previously described. FIG. 7 is a block diagram of a negative boost circuit arrangement suitable for providing a negative boost to the voltage of a bitline of a column of SRAM memory cells in accordance with one embodiment.

In the embodiment of FIG. 7, SRAM macro 110 includes a negative boost circuit arrangement, which can be implemented, for example, as part of write circuitry 220 of FIG. 2. The illustrated negative boost circuit arrangement includes a negative boost circuit 700 having a first input 701 that receives a bitline boost control signal (BL_Boost_CTL) and a second input 703 that receives a bitline idle precharge signal (BL_Idle_PC). First input 401 is coupled to the input of an inverter 704 having an output coupled to the gate of a NMOS transistor 706 coupled between lower supply voltage V_{SS} and a node 714. Node 714 is, in turn, connected to second plate 710 of boost capacitor 706, which can be formed of metal wires as previously described. Negative boost circuit 700 additionally includes a two-input NOR gate 712 having a first input coupled to the output of inverter 704 and a second input coupled to receive BL_Idle_PC signal from second input 403. The output of NOR gate 712 is coupled through an inverter 716 to first plate 708 of boost capacitor 706, which is the active plate.

During an idle period between accesses to SRAM cell array 200, macro controller 210 sets the BL_Boost_CTL signal logic low (e.g., 0b0), causing NMOS transistor 706 to be turned on to set node 714 connected to second plate 710 to lower supply voltage V_{SS}. In addition, macro controller 210 sets the BL_Idle_PC signal logic low (e.g., 0b0), causing first plate 708 to be set to the opposite voltage state from second plate 710 (i.e., logic high). When a boost operation is active (e.g., during a write access to SRAM cell array 200), macro controller 210 selectively asserts (e.g., switches to 0b1) the BL_Boost_CTL signal and continues to maintain the BL_Idle_PC signal logic low. As a result, the output of NOR gate 712 changes from logic low to logic high, which switches the voltage on first plate 308 from the logic high state to the logic low state. This voltage change provides a coupling action to second plate 710 and thus negatively boosts the voltage of second plate 710 and node 714 below V_{SS}. Asserting the BL_Boost_CTL signal also disconnects second plate 710 from upper supply voltage V_{SS}, enabling the voltage of second plate 710 to float in order to allow the coupling effect of first plate 708 switching states to impact the voltage state of second plate 710.

The negative boost circuit arrangement of FIG. 7 additionally includes a respective column assist circuit 720 for each of the columns of SRAM cell array 200. Each column assist circuit 720 includes a first pair of series-connected NMOS transistors 722, 724, which is coupled between the BLT of the associated column of memory cells 202 and node 714, and a second pair of series-connected NMOS transistors 726, 728, which is coupled between the BLC (or B̅L̅) and node 714. The gates of NMOS transistors 722, 726 are respectively controlled by macro controller 210 via BS_WR<0> and BS_WR<1> signals. The gates of NMOS transistors 724, 728 are respectively controlled by macro controller 210 via GBLTW<0> and GBLTW<1> signals. In order to write a “1” to a memory cell 202, macro controller 210 asserts the relevant wordline 204 (which may optionally have a positive voltage boost applied as discussed above) and additionally asserts BS_WR<1> and GBLTW<1> signals. Assertion of the BS_WR<1> and GBLTW<1> signals applies the voltage present at node 714 to BLC, causing the memory cell 202 to store a “1”. Conversely, to write a “0” to a memory cell, macro controller 210 asserts the BS_WR<0> and GBLTW<0> signals, applying voltage present at node 714 to BLT, causing the memory cell 202 to store a “0”.

In practice, the gates of NMOS transistors 722 and 726 can driven by the same control signal, for example, BS_WR<0>, and the gates of NMOS transistors 724 and 728 can be controlled by the true and complement of the relevant bit of write data. With this arrangement, during a write operation to the illustrated column of SRAM cell array 202, macro controller 210 asserts high BS_WR<0> to open both of NMOS transistors 722 and 726. Depending on which of NMOS transistors 724 or 728 is opened by the write data bit, a “0” is written to BLT or BLC, respectively. With this arrangement, BS_WR<1> could then be connected to a neighboring memory cell to select whether or not to write to a different column's bit lines 206. It should be noted that with the disclosed boost circuit arrangements, macro controller 210 can selectively provide a positive voltage boost to a wordline 204 and/or a positive voltage boost to an upper cell supply voltage rail 400 and/or a negative voltage boost to a bitline 206. Further, macro controller 210 can apply multiple of these voltage boosts concurrently.

Referring now to FIG. 8, there is depicted a timing diagram that illustrates the application of a negative boost voltage to a bitline of a SRAM cell array 200 during a write operation in accordance with one embodiment. For write operations in which macro controller 210 does not apply a negative boost voltage, the voltage at node 714 is set to V_{SS} by negative boost circuit 700. Consequently, the voltage of a bitline 206 (i.e., BLT or BLC) to which a write is made drops only to approximately V_{SS}, as shown by voltage curve 800. However, if macro controller 210 elects to apply a negative boost voltage, negative boost circuit 700 boosts the voltage at node 714 below V_{SS}. The voltage of a bitline 206 to which a write is made is therefore boosted below V_{SS}, as indicated by curve 802.

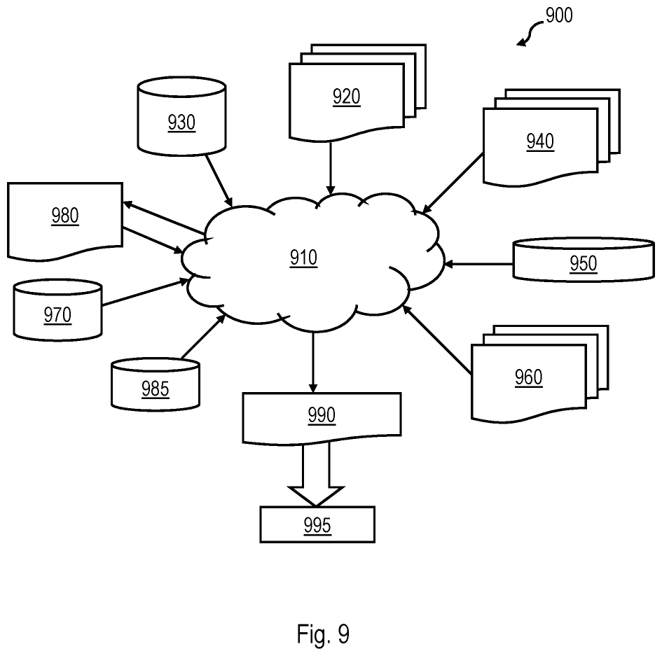

Referring now to FIG. 9, there is depicted a block diagram of an exemplary design flow 900 used for example, in semiconductor IC logic design, simulation, test, layout, and manufacture. Design flow 900 includes processes, machines and/or mechanisms for processing design structures or devices to generate logically or otherwise functionally equivalent representations of the design structures and/or devices described above. The design structures processed and/or generated by design flow 900 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Altera® Inc. or Xilinx® Inc.

FIG. 9 illustrates multiple such design structures including an input design structure 920 that is preferably processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as those shown herein. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown herein to generate a netlist 980 which may contain design structures such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, or buffer space.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 10 nm, 20 nm, 30 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990. Design structure 990 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown herein. In one embodiment, design structure 990 may comprise a compiled, executable HDL simulation model that functionally simulates one or more of the devices shown herein.

Design structure 990 may also employ a data format used for the exchange of layout data of integrated circuits and/or symbolic data format (e.g., information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown herein. Design structure 990 may then proceed to a stage 995 where, for example, design structure 990: proceeds to tape-out, is released to manufacturing, is released to a mask house, is sent to another design house, is sent back to the customer, etc.

As has been described, in at least one embodiment, an integrated circuit includes a semiconductor substrate and integrated circuitry on the semiconductor substrate. The integrated circuitry includes a static random access memory (SRAM) cell array and a first assist circuit and a differently configured second assist circuit. The first assist circuit is configured to apply a voltage boost to an access line utilized to access the SRAM cell array, and the second assist circuit is configured to apply a voltage boost to a voltage supply rail of the SRAM cell array. A common boost capacitor is coupled to selectively and concurrently provide a voltage boost to both the access line and the power rail via the first and second assist circuits, respectively.

While various embodiments have been particularly shown and described, it will be understood by those skilled in the art that various changes in form and detail may be made therein without departing from the spirit and scope of the appended claims and these alternate implementations all fall within the scope of the appended claims. For example, although aspects have been described with respect to a computer system executing program code that directs the functions of the present invention, it should be understood that present invention may alternatively be implemented as a program product including a computer-readable storage device storing program code that can be processed by a processor of a data processing system to cause the data processing system to perform the described functions. The computer-readable storage device can include volatile or non-volatile memory, an optical or magnetic disk, or the like, but excludes non-statutory subject matter, such as propagating signals per se, transmission media per se, and forms of energy per se.

As an example, the program product may include data and/or instructions that when executed or otherwise processed on a data processing system generate a logically, structurally, or otherwise functionally equivalent representation (including a simulation model) of hardware components, circuits, devices, or systems disclosed herein. Such data and/or instructions may include hardware-description language (HDL) design entities or other data structures conforming to and/or compatible with lower-level HDL design languages such as Verilog and VHDL, and/or higher level design languages such as C or C++. Furthermore, the data and/or instructions may also employ a data format used for the exchange of layout data of integrated circuits and/or symbolic data format (e.g. information stored in a GDSII (GDS2), GL1, OASIS, map files, or any other suitable format for storing such design data structures).

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. An integrated circuit, comprising:
a semiconductor substrate;
integrated circuitry on the semiconductor substrate, wherein the integrated circuitry includes:
a static random access memory (SRAM) cell array;
a first assist circuit and a differently configured second assist circuit, wherein the first assist circuit is configured to apply a voltage boost to an access line utilized to access the SRAM cell array and the second assist circuit is configured to apply a voltage boost to a voltage supply rail of the SRAM cell array; and
a common boost capacitor coupled to selectively and concurrently provide a voltage boost to both the access line and the power rail via the first and second assist circuits, respectively.

2. The integrated circuit of claim 1, wherein boost capacitor comprises a plurality of metal lines overlaying the SRAM cell array.

3. The integrated circuit of claim 1, wherein:
the access line comprises a wordline of the SRAM cell array.

4. The integrated circuit of claim 1, wherein:
the voltage supply rail comprises an upper voltage supply rail of the SRAM cell array.

5. The integrated circuit of claim 1, wherein:
the common boost capacitor is a first boost capacitor providing a positive voltage boost;
the integrated circuitry further includes:
a second boost capacitor providing a negative voltage boost; and
a third assist circuit coupled to the second boost capacitor and further coupled to selectively apply the negative voltage boost to a bitline of the SRAM cell array.

6. The integrated circuit of claim 1, further comprising a controller coupled to the first and second assist circuit and configured to control selective application of the voltage boost to the access line and to the voltage supply rail.

7. The integrated circuit of claim 1, wherein:
the boost capacitor includes a first plate and a second plate;
the boost capacitor is a component of a boost circuit including:
a boost control input coupled to receive a boost control signal;
a switch coupled between a cell supply voltage source and the second plate of the boost capacitor, wherein the switch is configured to couple the second plate to the cell supply voltage source based on the boost control signal being deasserted; and
a logic circuit configured to switch a voltage state of the first plate based on the boost control signal being asserted in order to boost voltage on the second plate by capacitive coupling.

8. A method, comprising:
providing an integrated circuit, including integrated circuitry on the semiconductor substrate, wherein the integrated circuitry includes:
a static random access memory (SRAM) cell array;
a first assist circuit and a differently configured second assist circuit, wherein the first assist circuit is configured to apply a voltage boost to an access line utilized to access the SRAM cell array and the second assist circuit is configured to apply a voltage boost to a voltage supply rail of the SRAM cell array; and
a common boost capacitor coupled to selectively provide a voltage boost to both the access line and the power rail via the first and second assist circuits, respectively; and
setting one or more control signals to cause a boost voltage on the common boost capacitor to be concurrently applied to the access line via the first assist circuit and to the voltage supply rail via the second assist circuit.

9. The method of claim 8, wherein boost capacitor comprises a plurality of metal lines overlaying the SRAM cell array.

10. The method of claim 8, wherein:
the access line comprises a wordline of the SRAM cell array.

11. The method of claim 8, wherein:
the voltage supply rail comprises an upper voltage supply rail of the SRAM cell array.

12. The method of claim 8, wherein:
the common boost capacitor is a first boost capacitor providing a positive voltage boost;
the integrated circuitry further includes:
a second boost capacitor providing a negative voltage boost;
a third assist circuit coupled to the second boost capacitor and further coupled to selectively apply the negative voltage boost to a bitline of the SRAM cell array; and
the method further includes applying the negative voltage boost to the bitline via the third assist circuit concurrently with the positive voltage boost provided by the first boost capacitor.

13. The method of claim 8, wherein:
the boost capacitor includes a first plate and a second plate;
the method further comprises:
based on a boost control signal being deasserted, coupling a cell supply voltage source to the second plate of the boost capacitor, wherein the switch is configured to couple the second plate to the cell supply voltage source; and
based on the boost control signal being asserted, switching a voltage state of the first plate to boost voltage on the second plate by capacitive coupling.

14. A design structure tangibly embodied in a machine-readable storage device for designing, manufacturing, or testing an integrated circuit, the design structure comprising:
an integrated circuit, including:
a semiconductor substrate;
integrated circuitry on the semiconductor substrate, wherein the integrated circuitry includes:
a static random access memory (SRAM) cell array;
a first assist circuit and a differently configured second assist circuit, wherein the first assist circuit is configured to apply a voltage boost to an access line utilized to access the SRAM cell array and the second assist circuit is configured to apply a voltage boost to a voltage supply rail of the SRAM cell array; and
a common boost capacitor coupled to selectively and concurrently provide a voltage boost to both the access line and the power rail via the first and second assist circuits, respectively.

15. The design structure of claim 14, wherein boost capacitor comprises a plurality of metal lines overlaying the SRAM cell array.

16. The design structure of claim 14, wherein:
the access line comprises a wordline of the SRAM cell array.

17. The design structure of claim 14, wherein:
the voltage supply rail comprises an upper voltage supply rail of the SRAM cell array.

18. The design structure of claim 14, wherein:
the common boost capacitor is a first boost capacitor providing a positive voltage boost;
the integrated circuitry further includes:
a second boost capacitor providing a negative voltage boost; and
a third assist circuit coupled to the second boost capacitor and further coupled to selectively apply the negative voltage boost to a bitline of the SRAM cell array.

19. The design structure of claim 14, further comprising a controller coupled to the first and second assist circuit and configured to control selective application of the voltage boost to the access line and to the voltage supply rail.

20. The design structure of claim 14, wherein:
the boost capacitor includes a first plate and a second plate;
the boost capacitor is a component of a boost circuit including:
a boost control input coupled to receive a boost control signal;
a switch coupled between a cell supply voltage source and the second plate of the boost capacitor, wherein the switch is configured to couple the second plate to the cell supply voltage source based on the boost control signal being deasserted; and
a logic circuit configured to switch a voltage state of the first plate based on the boost control signal being asserted in order to boost voltage on the second plate by capacitive coupling.
